(19) United States
(12) Patent Application Publication
(10) Pub. No.: US 2025/0081455 A1
(43) Pub. Date: Mar. 6, 2025

(54) Semiconductor Structure and Method for Forming the Same

(71) Applicants: Hua Hong Semiconductor (Wuxi) Limited, Wuxi (CN); Shanghai Huahong Grace Semiconductor Manufacturing Corporation, Shanghai (CN)

(72) Inventors: Guoqing CHENG, Wuxi (CN); Haiyang ZHOU, Shanghai (CN); Xianzhou LIU, Shanghai (CN); Huiyi WANG, Wuxi (CN); Quanhao SHEN, Wuxi (CN)

(73) Assignees: Hua Hong Semiconductor (Wuxi) Limited, Wuxi (CN); Shanghai Huahong Grace Semiconductor Manufacturing Corporation, Shanghai (CN)

(21) Appl. No.: 18/819,494

(22) Filed: Aug. 29, 2024

(30) Foreign Application Priority Data
Aug. 31, 2023 (CN) 202311120309.X

(51) Int. Cl. H10B 41/30; H01L 21/28; H01L 29/66; H01L 29/788

(52) U.S. Cl. CPC H10B 41/30; H10D 30/0411; H10D 30/683; H10D 64/035

(57) ABSTRACT

A semiconductor structure and a method for forming the semiconductor structure are provided. The method includes: providing a substrate; forming a plurality of initial memory cell structures on the substrate, and an initial memory cell structure including a floating gate dielectric layer disposed on the substrate, an initial floating gate disposed on the floating gate dielectric layer, a mask structure disposed on the initial floating gate, a control gate dielectric layer disposed on the initial floating gate and on sidewalls of the mask structure, and a control gate disposed on the control gate dielectric layer disposed on both sides of the mask structure; removing the mask structure to form an initial opening; etching the initial floating gate and the floating gate dielectric layer disposed at a bottom of the initial opening to form a word line opening; and forming a word line structure in the word line opening.

### CROSS-REFERENCE TO RELATED APPLICATIONS

This application claims the priority to Chinese Application No. 202311120309.X, filed on Aug. 31, 2023, and entitled “SEMICONDUCTOR STRUCTURE AND METHOD FOR FORMING THE SAME”, the content of which is incorporated herein by reference in their entirety.

### TECHNICAL FIELD

The present disclosure generally relates to semiconductor technology field, and specifically, to a semiconductor structure and a method for forming the semiconductor structure.

### BACKGROUND

Embedded flash memory is a non-volatile memory that is widely used in automotive, consumer and other fields. With a rapid increase of market demand for new energy vehicles in recent years, demands for chip storage, processing performance and cost have also increased rapidly. Research institutions are focusing on the layout and development of flash memory devices which have high write and erase performance.

At present, a memory cell of a common flash memory device includes a floating gate dielectric layer, a floating gate disposed on the floating gate dielectric layer, an oxide-nitride-oxide dielectric layer disposed on the floating gate, and a control gate disposed on the oxide-nitride-oxide dielectric layer. A sidewall of the floating gate is provided with a tunneling dielectric layer, and an erase gate is disposed between adjacent memory cells.

However, in the existing technology, a process window for forming the flash memory device is small, resulting in many defects, which is not conducive to miniaturization of the device. Further, the device also needs to be improved in stability.

### SUMMARY

A semiconductor structure and a method for forming the semiconductor structure are provided according to embodiments of the present disclosure. The process window is broadened for forming a flash memory device, and device defects are reduced, thereby conducive to miniaturization of the device and improving a stability of the device.

For solving above-mentioned problems, a semiconductor structure is provided according to embodiments of the present disclosure. The semiconductor structure includes: a substrate; a floating gate dielectric layer disposed on the substrate; a word line structure disposed on a surface of the floating gate dielectric layer; a floating gate disposed on both sidewalls of the word line structure and on the floating gate dielectric layer; a control gate dielectric layer disposed on the both sidewalls of the word line structure and on the floating gate; and a control gate disposed on the control gate dielectric layer and on both sides of the word line structure.

According to some embodiments, one side of the floating gate proximate to the word line structure has a sharp tip.

According to some embodiments, the semiconductor structure further includes a tunneling oxide layer disposed on the both sidewalls of the word line structure. The tunneling oxide layer is disposed between the word line structure and the control gate and between the word line structure and the floating gate.

According to some embodiments, the semiconductor structure further includes a silicide layer disposed on the word line structure and on a sidewall surface of the control gate away from the word line structure.

Accordingly, a method for forming a semiconductor structure is provided according to embodiments of the present disclosure. The method includes: providing a substrate; forming a plurality of initial memory cell structures on the substrate, and an initial memory cell structure including a floating gate dielectric layer disposed on the substrate, an initial floating gate disposed on the floating gate dielectric layer, a mask structure disposed on the initial floating gate, a control gate dielectric layer disposed on the initial floating gate and on sidewalls of the mask structure, and a control gate disposed on the control gate dielectric layer disposed on both sides of the mask structure; removing the mask structure to form an initial opening, and the initial floating gate being exposed through the initial opening; etching the initial floating gate and the floating gate dielectric layer disposed at a bottom of the initial opening to form a word line opening between adjacent control gates and between adjacent control gate dielectric layers to expose the substrate; and forming a word line structure in the word line opening.

According to some embodiments, forming the initial memory cell structure includes: forming a floating gate dielectric material layer on the substrate and forming a floating gate material layer on the floating gate dielectric material layer; forming a plurality of mask structures on the floating gate material layer, and the plurality of mask structures being separated from each other; forming a control gate dielectric material layer on the floating gate material layer, and on the sidewalls and a top surface of the mask structure; forming the control gate on the control gate dielectric material layer, and the control gate being disposed on the both sidewalls of the mask structure and on the control gate dielectric material layer disposed on the floating gate material layer; and etching the control gate dielectric material layer, the floating gate material layer and the floating gate dielectric material layer with the control gate as a mask to form the control gate dielectric layer, the initial floating gate and the floating gate dielectric layer.

According to some embodiments, the method further includes: after forming the mask structure and before forming the control gate dielectric material layer, forming a compensation sidewall on both sidewalls of the mask structure and on the floating gate material layer; after removing the mask structure, etching the initial floating gate with the compensation sidewall as a mask to form a floating gate; and after forming the floating gate, removing the compensation sidewall.

According to some embodiments, the floating gate having a sharp tip is exposed through the word line opening.

According to some embodiments, the method further includes: during forming the mask structure, etching the floating gate material layer to make the floating gate material layer have a rounded corner disposed at a bottom of the both sidewalls of the mask structure.

According to some embodiments, the method further includes: after forming the word line structure, forming a silicide layer on the word line structure and on a sidewall surface of the control gate away from the word line structure.

According to some embodiments, the method further includes: after forming the word line opening and before forming the word line structure, depositing a tunneling oxide layer on a surface of the control gate dielectric layer and on a surface of the floating gate which is exposed through the word line opening.

Compared with existing technology, embodiments of the present disclosure may have following advantages.

According to some embodiments of the present disclosure, in the method for forming the semiconductor structure, before the word line structure is formed, the mask structure is first formed at a location where the word line structure is formed subsequently, and then the control gate and the control gate dielectric layer are formed on both sides of the mask structure. Therefore, defects and breakage of sidewalls of the control gate caused by a conventional process for etching the control gate and the control gate dielectric layer can be avoided. According to some embodiments of the present disclosure, since the control gate dielectric layer with good continuity is formed on the sidewalls of the mask structure, an interface between the control gate dielectric layer and the subsequently formed word line structure will not be affected by the etching process, thereby reducing defects and a risk of breakage. Moreover, the control gate dielectric layer disposed between the control gate and the word line structure can serve as an isolation structure between the word line structure and the control gate, so there is no need to form an additional isolation sidewall, which is beneficial to miniaturization of the device.

According to some embodiments of the present disclosure, the floating gate having a sharp tip is exposed through the word line opening, and the sharp tip is conductive to forming a relative concentrated electric field, which is beneficial to improving erasing efficiency.

According to some embodiments of the present disclosure, in the semiconductor structure, since the control gate dielectric layer is disposed between the control gate and the word line structure, the control gate dielectric layer can serve as an isolation structure between the word line structure and the control gate, so there is no need to form an additional isolation sidewall, which is beneficial to miniaturization of the device.

### BRIEF DESCRIPTION OF THE DRAWINGS

FIG. 1 to FIG. 10 schematically illustrate cross-sectional views of intermediate structural diagrams according to a process for forming a semiconductor structure in some embodiments of the present disclosure.

### DETAILED DESCRIPTION

As described in the background, a memory cell of a common flash memory device includes a floating gate dielectric layer, a floating gate disposed on the floating gate dielectric layer, an oxide-nitride-oxide dielectric layer disposed on the floating gate, and a control gate disposed on the oxide-nitride-oxide dielectric layer. A sidewall of the floating gate is provided with a tunneling dielectric layer, and an erase gate is disposed between adjacent memory cells.

However, in the existing technology, a process window for forming the flash memory device is small, resulting in many defects, which is not conducive to miniaturization of the device. Further, the device also needs to be improved in stability.

For solving above problems, a semiconductor structure and a method for forming the semiconductor structure are provided according to some embodiments of the present disclosure. Before a word line structure is formed, a mask structure is first formed at a location where the word line structure is formed subsequently, and then a control gate and a control gate dielectric layer are formed on both sides of the mask structure. Therefore, defects and breakage of sidewalls of the control gate caused by a conventional process for etching the control gate and the control gate dielectric layer can be avoided. According to some embodiments of the present disclosure, since the control gate dielectric layer with good continuity is formed on the sidewalls of the mask structure, an interface between the control gate dielectric layer and the subsequently formed word line structure will not be affected by the etching process, thereby reducing defects and a risk of breakage. Moreover, the control gate dielectric layer disposed between the control gate and the word line structure can serve as an isolation structure between the word line structure and the control gate, so there is no need to form an additional isolation sidewall, which is beneficial to miniaturization of the device.

In order to clarify the object, features and advantages of embodiments of the present disclosure, embodiments of present disclosure will be described in detail in conjunction with accompanying figures.

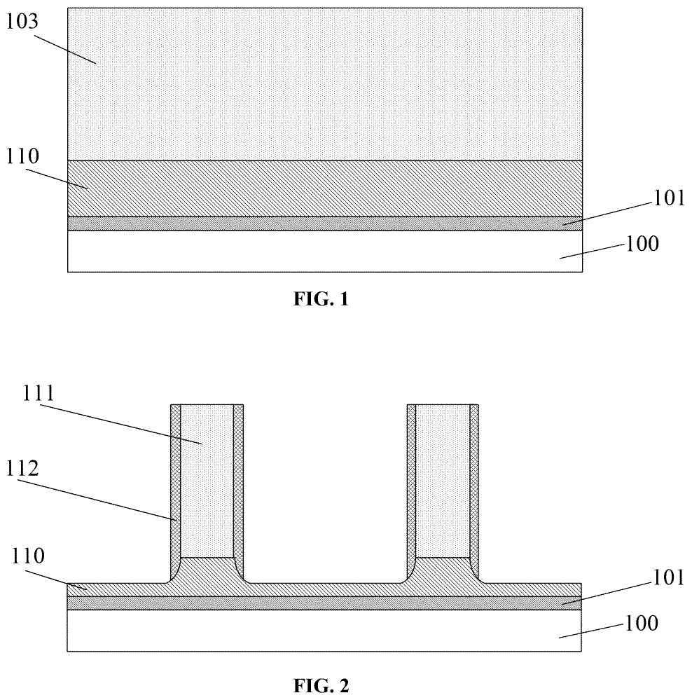

FIG. 1 to FIG. 10 schematically illustrate cross-sectional views of intermediate structural diagrams according to a process for forming a semiconductor structure in some embodiments of the present disclosure.

Referring to FIG. 1, a substrate 100 is provided, a floating gate dielectric material layer 101 is formed on the substrate 100, forming a floating gate material layer 110 is formed on the floating gate dielectric material layer 101, and a mask material layer 103 is formed on the floating gate material layer 110.

The substrate 100 may be made of a material including silicon, silicon germanium, silicon carbide, Silicon On Insulator (SOI), Germanium On Insulator (GOI), or the like. Specifically, according to some embodiments, the substrate 100 is made of silicon.

According to some embodiments, the floating gate material layer 110 is made of a material including polycrystalline silicon.

According to some embodiments, mask material layer 103 is made of a material including silicon nitride.

Referring to FIG. 2, the mask material layer 103 is patterned and etched to form a plurality of mask structures 111 on the floating gate material layer 110, and the plurality of mask structures 111 are separated from each other. A compensation sidewall 112 is formed on both sidewalls of the mask structure 111 and on the floating gate material layer 110.

According to some embodiments, the method further includes: during forming the mask structure, etching the floating gate material layer 110 to make the floating gate material layer have a rounded corner disposed at a bottom of the both sidewalls of the mask structure 111. The compensation sidewall 112 is also formed on the rounded corner.

According to some embodiments, during a process for etching the floating gate material layer 110, morphology of the etched floating gate material layer 110 can be adjusted by increasing isotropic etching, such that the floating gate material layer 110 has the rounded corner disposed at the bottom of the sidewalls of the mask structure 111.

According to some embodiments, the rounded corner is conducive to exposing the floating gate having a sharp tip after the mask structure 111 is subsequently removed. The sharp tip is conductive to forming a relative concentrated electric field, which is conducive to improving the erasing efficiency.

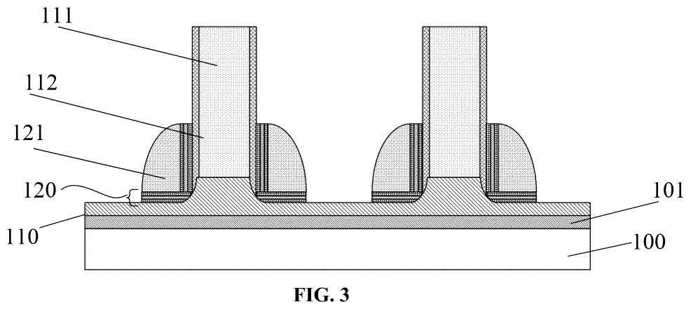

Referring to FIG. 3, a control gate dielectric material layer (not shown) is formed on the floating gate material layer 110, and on the sidewalls and a top surface of the mask structure 111. A control gate 121 is formed on the control gate dielectric material layer, and the control gate 121 is disposed on the both sidewalls of the mask structure 111 and on the control gate dielectric material layer disposed on the floating gate material layer 110. The control gate dielectric material layer is etched with the control gate 121 as a mask to form a control gate dielectric layer 120, and the control gate dielectric layer 120 is disposed between a bottom of the control gate 121 and a surface of the floating gate material layer 110, and also disposed between a sidewall of the control gate 121 and the compensation sidewall 112.

According to some embodiments, a process for forming the control gate 121 includes: forming a control gate material layer (not shown) on the control gate dielectric material layer, and etching the control gate material layer with the mask structure 111 as a mask to form the control gate 121 on both sides of the mask structure 111.

According to some embodiments, a surface of the control gate 121 away from the mask structure 111 takes a circular shape.

According to some embodiments, the control gate 121 is made of a material including polycrystalline silicon.

According to some embodiments, the control gate dielectric layer 120 includes: a silicon oxide layer, a silicon nitride layer disposed on a surface of the silicon oxide layer, and a silicon oxide layer disposed on a surface of the silicon nitride layer.

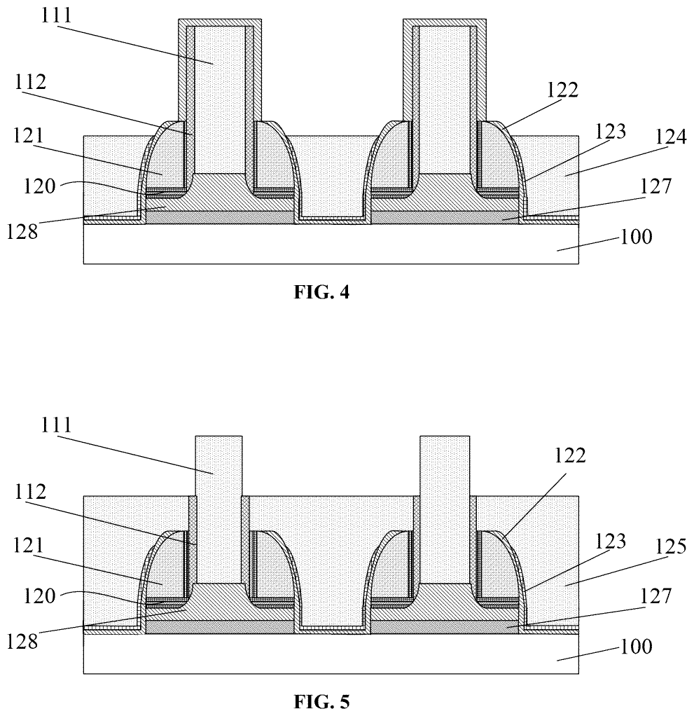

Referring to FIG. 4, the floating gate material layer 110 and the floating gate dielectric material layer 101 are etched with the control gate 121 as a mask to form an initial floating gate 128 and a floating gate dielectric layer 127. Therefore, a plurality of initial memory cell structures (not labeled) are formed on the substrate 100.

According to some embodiments, an initial memory cell structure includes: a floating gate dielectric layer 127 disposed on the substrate 100; an initial floating gate 128 disposed on the floating gate dielectric layer 127; a mask structure 111 disposed on the initial floating gate 128; a control gate dielectric layer 120 disposed on the initial floating gate 128 and on the sidewalls of the mask structure 111; and a control gate 121 disposed on the control gate dielectric layer 120 disposed on both sides of the mask structure 111.

Thereafter, a first oxide layer 122, and a first memory cell sidewall 123 disposed on a surface of the first oxide layer 122 are formed on both sidewalls of the initial memory cell structure.

According to some embodiments, the first memory cell sidewall 123 is made of a material including silicon nitride.

Specifically, the first oxide layer 122 and the first memory cell sidewall 123 are disposed on a sidewall surface of the control gate 121 away from the mask structure 111, on a sidewall surface of the control gate dielectric layer 120 away from the mask structure 111, on a sidewall surface of the initial floating gate 128 away from the mask structure 111, and on a sidewall surface of the floating gate dielectric layer 127 away from the mask structure 111.

According to some embodiments, a process for forming the first memory cell sidewall 123 includes: forming the first oxide layer 122 and an initial first memory cell sidewall (not shown) on the substrate 100 and on the sidewalls and a top surface of the initial memory cell structure; forming a first oxide filler layer 124 on the substrate 100, and a height of the first oxide filler layer 124 being lower than or the same as a height of the control gate 121; and etching the first oxide filler layer 124 to expose the initial first memory cell sidewall to form a first memory cell sidewall 123.

Referring to FIG. 5, a second oxide filler layer 125 is formed on the first oxide filler layer 124, and a top of the second oxide filler layer 125 is higher than a top of the control gate 121 and lower than a top of the mask structure 111. The compensation sidewalls 112 exposed through the second oxide filler layer 125 is etched to expose a portion of the sidewalls of the mask structure 111.

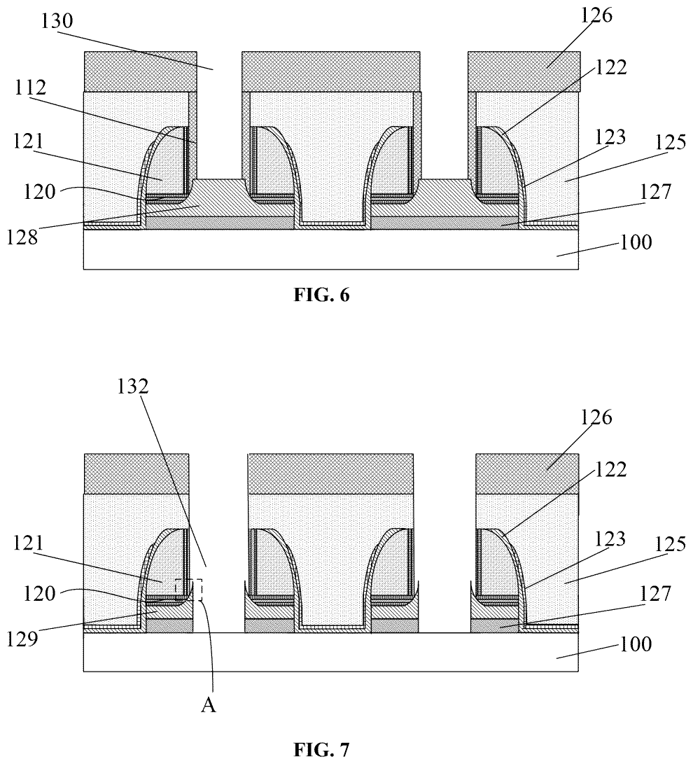

Referring to FIG. 6, a second mask layer 126 is formed on surfaces of the mask structure 111 and on the second oxide filler layer 125; the second mask layer 126 and the mask structure 111 are planarized; and the mask structure 111 is removed to form an initial opening 130, and the initial floating gate 128 is exposed through the initial opening 130.

According to some embodiments, the second oxide filler layer 125 is made of a material including silicon nitride or silicon oxide.

According to some embodiments, a method for removing the mask structure 111 includes wet etching.

Referring to FIG. 7, a portion of the initial floating gate 128 disposed at a bottom of the initial opening 130 is etched with the compensation sidewall 112 as a mask to form a floating gate 129. After the floating gate 129 is formed, the compensation sidewall 112 is removed, and then the floating gate dielectric layer 127 is etched until the substrate 100 is exposed to form a word line opening 132 between adjacent control gates 121 and between adjacent control gate dielectric layers 120.

According to some embodiments, the floating gate 129 having a sharp tip (as shown at A) is exposed through the word line opening 132. The sharp tip is conductive to forming a relative concentrated electric field, which facilitates improving erasing efficiency.

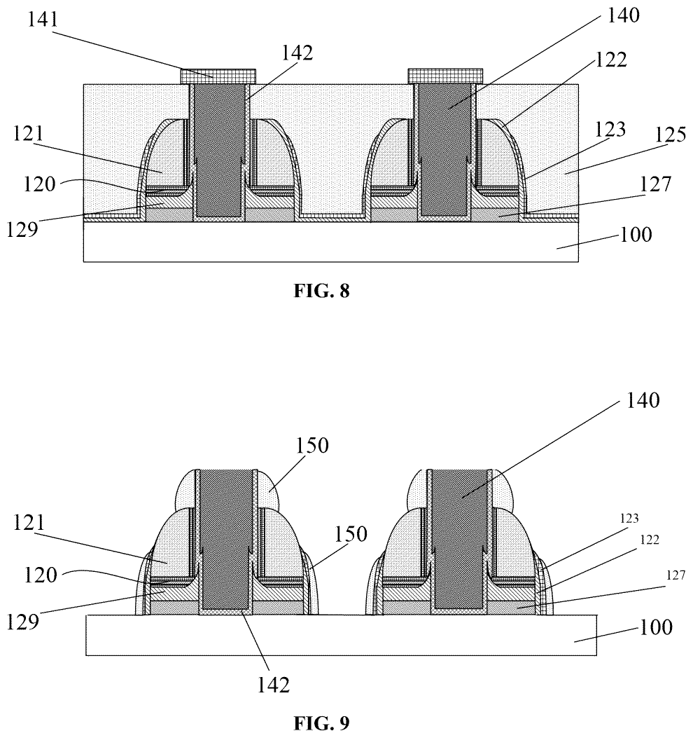

Referring to FIG. 8, a tunneling oxide layer 142 is deposited on the substrate 100 which is exposed through the word line opening 132, on a surface of the floating gate dielectric layer 127 which is exposed through the word line opening 132, on a surface of the floating gate 129 which is exposed through the word line opening 132, on a surface of the control gate dielectric layer 120 which is exposed through the word line opening 132, on a surface of the second oxide filler layer 125 which is exposed through the word line opening 132, and on a surface of the second mask layer 126 which is exposed through the word line opening 132. A word line structure 140 is formed in the word line opening 132, and a protective layer 141 is formed on the word line structure 140.

According to some embodiments, the word line structure 140 is made of a material including polycrystalline silicon.

According to some embodiments, the protective layer 141 is made of a material including silicon oxide.

According to some embodiments, a process for forming the word line structure 140 includes: forming a word line material layer (not shown) on the tunneling oxide layer 142 exposed through the word line opening 132 and on the tunneling oxide layer 142 disposed on the second mask layer 126; and planarizing the word line material layer until the second oxide filler layer 125 is exposed to form the word line structure 140.

According to some embodiments, the word line structure 140 also acts as an erasing gate.

According to some embodiments, a height of the word line structure 140 is higher than a height of the control gate 121, and the difference in height facilitates a good isolation between the word line structure 140 and the control gate 121.

Referring to FIG. 9, the second oxide filler layer 125 is removed and the first oxide layer 122 disposed on the sidewall of the control gate 121 is etched to expose a portion of the sidewall of the control gate 121. Thereafter, a second memory cell sidewall 150 is formed on a surface of the first memory cell sidewall 123 and formed between the word line structure 140 and the control gate 121.

According to some embodiments, the first memory cell sidewall 123 is covered by the second memory cell sidewall 150, and the second memory cell sidewall 150 is disposed between a top of the word line structure 140 and a top of the control gate 121.

According to some embodiments, the first memory cell sidewall 123 and the second memory cell sidewall 150 disposed on the surface of the first memory cell sidewall 123 are used to control injection positions of subsequent ion doping. The second memory cell sidewall 150 disposed between the top of the word line structure 140 and the top of the control gate 121 is used to further isolate the word line structure 140 and the control gate 121.

According to some embodiments, the second memory cell sidewall 150 is made of a material including silicon nitride or silicon oxide.

Thereafter, the protective layer 141 is removed.

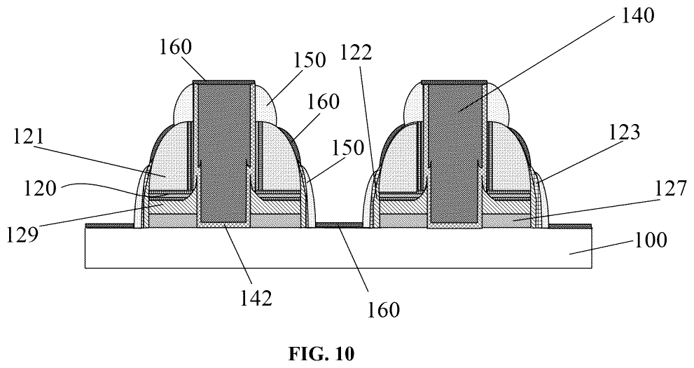

Referring to FIG. 10, a self-aligned silicide material layer (not shown) is formed on a surface of the second memory cell sidewall 150, on a surface of the control gate 121, on the word line structure 140, and on substrate 100; and the self-aligned silicide material layer is patterned and etched to form a silicide layer 160 on the top of the word line structure 140, on a sidewall surface of the control gate 121 away from the word line structure 140, and on the substrate 100 (which is subsequently used as a source-drain region of the device) disposed on both sides of the word line structure 140.

According to some embodiments, the silicide layer 160 disposed on the surface of the control gate 121 is formed on the exposed surface of the control gate 121 after the first oxide layer 122 is etched, and the sidewall of the control gate 121 is exposed between the second memory cell sidewall 150 on the surface of the first memory cell sidewall 123 and the second memory cell sidewall 150 on the top of the control gate 121.

The sidewall of the control gate 121 disposed between the second memory cell sidewall 150 on the surface of the first memory cell sidewall 123 and the second memory cell sidewall 150 on the top of the control gate 121 can be exposed through an etching process and has a surface of large area. Therefore, a silicide layer 160 of large area can be formed on the exposed sidewall of the control gate 121, which reduces a resistance of the control gate 121 electrically connected with an external circuitry, reduces the circuitry delay, and improves efficiency of the flash memory device.

Thereafter, an etch stop layer (not shown) is formed on the word line structure 140 and on a surface of the silicide layer 160 disposed on the control gate 121; and an interlayer dielectric layer (not shown) is formed, and the word line structure 140, the control gate 121, the control gate dielectric layer 120, the floating gate 129, and the floating gate dielectric layer 127 are wrapped by the interlayer dielectric layer.

In summary, before the word line structure 140 is formed, the mask structure 111 is first formed at a location where the word line structure 140 is formed subsequently, and then the control gate 121 and the control gate dielectric layer 120 are formed on both sides of the mask structure 111. Therefore, defects and breakage of sidewalls of the control gate 121 caused by a conventional process for etching the control gate 121 and the control gate dielectric layer 120 can be avoided. According to some embodiments of the present disclosure, since the control gate dielectric layer with good continuity is formed on the sidewalls of the mask structure 111, an interface between the control gate dielectric layer and the subsequently formed word line structure 140 will not be affected by multiple processes for etching the control gate material layer, the control gate dielectric material layer, the floating gate material layer 110, and the floating gate dielectric material layer 101, and the like. Therefore, defects and a risk of breakage are reduced, and it is conductive to miniaturizing the device. Moreover, the control gate dielectric layer 120 disposed between the control gate 121 and the word line structure 140 can serve as an isolation structure between the word line structure 140 and the control gate 121, so there is no need to form an additional isolation sidewall, which is beneficial to miniaturization of the device.

Accordingly, some embodiments of the present disclosure also provide a semiconductor structure formed by the method described above.

Referring to FIG. 10, the semiconductor structure includes: a substrate 100; a floating gate dielectric layer 127 disposed on the substrate 100; a word line structure 140 disposed on a surface of the floating gate dielectric layer 127; a floating gate 129 disposed on both sidewalls of the word line structure 140 and on the floating gate dielectric layer 127; a control gate dielectric layer 120 disposed on the both sidewalls of the word line structure 140 and on the floating gate 129; and a control gate 121 disposed on the control gate dielectric layer 120 and on both sides of the word line structure 140.

According to some embodiments, one side of the floating gate 129 proximate to the word line structure 140 has a sharp tip.

According to some embodiments, the semiconductor structure further includes a tunneling oxide layer 142 disposed on the both sidewalls of the word line structure 140. The tunneling oxide layer 142 is disposed between the word line structure 140 and the control gate 121 and between the word line structure 140 and the floating gate 129.

According to some embodiments, the semiconductor structure further includes a silicide layer 160. The silicide layer 160 is disposed on the word line structure 140 and on a sidewall surface of the control gate 121 away from the word line structure 140, and on the substrate 100 (which is subsequently used as a source-drain region of the device) disposed on both sides of the word line structure 140.

Although the present disclosure has been disclosed above, the present disclosure is not limited thereto. Those skilled in the art can modify and vary the embodiments without departing from the spirit and scope of the present disclosure. Therefore, the protection scope of the present disclosure should be based on the scope defined by the claims.

What is claimed is:

1. A semiconductor structure, comprising:
a substrate;
a floating gate dielectric layer disposed on the substrate;
a word line structure disposed on a surface of the floating gate dielectric layer;
a floating gate disposed on both sidewalls of the word line structure and on the floating gate dielectric layer;
a control gate dielectric layer disposed on the both sidewalls of the word line structure and on the floating gate; and
a control gate disposed on the control gate dielectric layer and on both sides of the word line structure.

2. The semiconductor structure according to claim 1, wherein one side of the floating gate proximate to the word line structure has a sharp tip.

3. The semiconductor structure according to claim 1, further comprising: a tunneling oxide layer disposed on the both sidewalls of the word line structure, wherein the tunneling oxide layer is disposed between the word line structure and the control gate and between the word line structure and the floating gate.

4. The semiconductor structure according to claim 1, further comprising: a silicide layer disposed on the word line structure and on a sidewall surface of the control gate away from the word line structure.

5. A method for forming a semiconductor structure, comprising:
providing a substrate;
forming a plurality of initial memory cell structures on the substrate, wherein an initial memory cell structure comprises: a floating gate dielectric layer disposed on the substrate, an initial floating gate disposed on the floating gate dielectric layer, a mask structure disposed on the initial floating gate, a control gate dielectric layer disposed on the initial floating gate and on sidewalls of the mask structure, and a control gate disposed on the control gate dielectric layer disposed on both sides of the mask structure;
removing the mask structure to form an initial opening, wherein the initial floating gate is exposed through the initial opening;
etching the initial floating gate and the floating gate dielectric layer disposed at a bottom of the initial opening to form a word line opening between adjacent control gates and between adjacent control gate dielectric layers to expose the substrate; and
forming a word line structure in the word line opening.

6. The method according to claim 5, wherein forming the initial memory cell structure comprises:
forming a floating gate dielectric material layer on the substrate and forming a floating gate material layer on the floating gate dielectric material layer;
forming a plurality of mask structures on the floating gate material layer, wherein the plurality of mask structures are separated from each other;
forming a control gate dielectric material layer on the floating gate material layer, and on the sidewalls and a top surface of the mask structure;
forming the control gate on the control gate dielectric material layer, wherein the control gate is disposed on the both sidewalls of the mask structure and on the control gate dielectric material layer disposed on the floating gate material layer; and
etching the control gate dielectric material layer, the floating gate material layer and the floating gate dielectric material layer with the control gate as a mask to form the control gate dielectric layer, the initial floating gate and the floating gate dielectric layer.

7. The method according to claim 6, further comprising:
after forming the mask structure and before forming the control gate dielectric material layer, forming a compensation sidewall on both sidewalls of the mask structure and on the floating gate material layer;
after removing the mask structure, etching the initial floating gate with the compensation sidewall as a mask to form a floating gate; and
after forming the floating gate, removing the compensation sidewall.

8. The method according to claim 7, wherein the floating gate having a sharp tip is exposed through the word line opening.

9. The method according to claim 6, further comprising: during forming the mask structure, etching the floating gate material layer to make the floating gate material layer have a rounded corner disposed at a bottom of the both sidewalls of the mask structure.

10. The method according to claim 5, further comprising: after forming the word line structure, forming a silicide layer on the word line structure and on a sidewall surface of the control gate away from the word line structure.

11. The method according to claim 5, further comprising: after forming the word line opening and before forming the word line structure, depositing a tunneling oxide layer on a surface of the control gate dielectric layer and on a surface of the floating gate which is exposed through the word line opening.
